(19) United States
(12) Patent Application Publication
(10) Pub. No.: US 2005/0059186 A1
(43) Pub. Date: Mar. 17, 2005

(54) Photoelectrochemical device and method of making

(76) Inventors: Nelson A. Kelly, Sterling Heights, MI (US); Thomas L. Gibson, Utica, MI (US)

Correspondence Address: General Motors Corporation -- Legal Staff;Kathryn A. Marra, Mail Code 482-C23-B21, P.O. Box 300, Detroit, MI, 48265-3000, US

(21) Appl. No.: 10/662,853

(22) Filed: Sep. 15, 2003

(51) Int. Cl. H01L 31/20; C25D 17/00; H01L 29/04

(52) U.S. Cl. 438/73; 204/242; 257/53

(57) ABSTRACT

The invention provides a method of making a photoelectrode and also provides a photoelectrode comprising a semiconductor layer having a first and second opposite major surfaces, with the first major surface overlaid with a layer of indium tin oxide having a thickness, crystal structure, and composition sufficient for robust operation in an electrochemical cell for electrolysis of water.

### FIELD OF THE INVENTION

This invention relates to photoelectrochemical (PEC) devices for the solar photoelectrolysis of water to produce hydrogen.

### BACKGROUND OF THE INVENTION

Currently the major process by which hydrogen is produced is by the steam reforming of methane. Another means of making hydrogen is by the electrolysis of water. The electricity required for electrolysis is mainly derived from the electric power grid, and the predominant source of grid electricity, combustion of fossil fuels, generates emissions, such as nitrogen oxides and particulate matter, as well as carbon dioxide. One way to eliminate such emissions is to use solar generated electricity to electrolyze water to make hydrogen. Presently, efforts are directed toward improving the efficiency, durability, and cost of the hydrogen production processes.

However, systems consisting of solar cells to make electricity together with electrolyzers to dissociate water into hydrogen and oxygen are costly compared to producing hydrogen by the steam reforming of methane.

### SUMMARY OF THE INVENTION

In one aspect, the invention provides a photoelectrochemical (PEC) electrode or photoelectrode for use in splitting water by electrolysis. The photoelectrode has an electrically conductive surface in contact with an electrolyte solution. This surface is an indium tin oxide layer, which is in electrical contact with the semiconductor solar cell material of the PEC photoelectrode. Such semiconductor solar cell is preferably a triple-junction amorphous silicon (a-Si) solar cell. Electrolyte solutions aggressively attack many kinds of surfaces including some metals and metal oxides by corrosion and dissolution. The indium tin oxide layer is robust with respect to aggressive attack by the electrolyte solution. The indium tin oxide (ITO) material is a transparent conductive oxide (TCO), thus, it is electrically conductive and transparent. Such indium-tin oxide (ITO) is an antireflection coating. The ITO coating of the present invention is a particular type of TCO coating.

In another embodiment, the invention provides a method of making the PEC electrode by sputter deposition of the ITO coating onto the surface of the PEC solar cell layer. In a broad aspect, deposition is by bombarding a target of indium oxide and tin oxide, with the indium oxide being present at an amount greater than the tin oxide. In a preferred aspect, the sputtering target is 90% In₂O₃/10% SnO₂ by weight. It can be appreciated that minor variations, less than 10% and on the order of 2% to 5% on the basis of 100 parts, is within the scope of the invention. The range of deposition conditions are: substrate temperature=150-260° C.; chamber pressure=6-12 mTorr; deposition time=at least 10 minutes and, preferably, up to at least 60 minutes; rf power=30 to 50 watts. Preferably, the atmosphere is non-oxidizing and is essentially free of oxygen and, most preferably, is argon or other inert gas. It is most preferred to have less than 1% by volume oxygen present and to exclude as much as possible to have essentially no oxygen. Desirably, the deposition time is at least 30 minutes, and the radio-frequency (rf) power is 40 watts and the substrate temperature is 200-260° C. The most preferred temperature is approximately 230° C. The chamber pressure is desirably about 8 mTorr. The longer deposition time yields a thicker deposited layer. Layer thicknesses in the range of 650-700 Angstroms are achieved at about 10 minutes, thickness of about 2000 to 2100 Angstroms at 30 minutes. The preferred thickness of 4200 Angstroms is achieved at about 60 minutes.

Further areas of applicability of the present invention will become apparent from the detailed description provided hereinafter. It should be understood that the detailed description and specific examples, while indicating the preferred embodiment of the invention, are intended for purposes of illustration only and are not intended to limit the scope of the invention.

### BRIEF DESCRIPTION OF THE DRAWINGS

The present invention will become more fully understood from the detailed description and the accompanying drawings, wherein:

FIG. 1 is a schematic, sectional, representation of a photoelectrochemical (PEC) device which comprises a photoelectrode and counter electrode housed in a container with basic aqueous (alkaline electrolyte) solution; with the PEC electrode having an ITO-coated major surface.

FIG. 2 is a bar chart showing performance for the coating of the invention (ITO-9) and comparative coatings ITO-1, ITO-3, ITO-6, ITO-8 and ITO-17. This shows the time to failure using a linear sweep technique.

FIG. 3 is a graph showing longer lifetime of a coated electrode of the invention as compared to an electrode with a standard ITO coating. It also shows current output of the cell according to the invention as compared to a standard ITO coated cell.

### DETAILED DESCRIPTION OF THE PREFERRED EMBODIMENTS

The following description of the preferred embodiment(s) is merely exemplary in nature and is in no way intended to limit the invention, its application, or uses.

In one aspect of the present invention, there is provided a photoelectrochemical (PEC) device for electrolysis of water to produce hydrogen. The PEC device comprises a container housing a photoelectrochemical (PEC) electrode (photoelectrode), a counter electrode and an electrolyte solution. In a preferred aspect of the PEC device the TCO-coated photoelectrode is the anode and produces oxygen, while the counter electrode is the cathode and produces hydrogen. The photoelectrode and the counter electrode are spaced apart from one another in the container, and each electrode is in contact with the electrolyte solution. Preferably, the counter electrode comprises a metal such as Pt or Ni that is stable under the reducing conditions at the cathode and has a low overvoltage for hydrogen production. The electrolyte solution comprises a solvent which preferably comprises water, and a solute which preferably comprises a base. In a preferred embodiment the electrolyte is a basic (alkaline) aqueous solution. Use of an acid instead of a base is also possible. An acid is not recommended due to corrosion problems, but use of an acid or neutral salt in the electrolyte solution instead of a base is within the scope of the invention. An external (not in the solution) electrically conductive path is provided between the photoelectrode and the counter electrode.

The photoelectrode comprises a semiconductor layer, typically and preferably triple-junction a-Si, having opposite major surfaces. The one major surface is an electrically conducting substrate. In a preferred arrangement the one major surface is stainless steel (ss) on top of which is deposited a layer of silver, a layer of ZnO₂, and then three layers of n-type, i-type, and p-type semiconductor materials (see Deng and Schiff, 2003, “Amorphous Silicon Based Solar Cells,” Chapter 12, pages 505-565 in Handbook of Photovoltaic Engineering, ed. A. Luque & S. Hegedus, by John Wiley & Sons, Ltd., such chapter separately published on Xunming Deng's website: http://www.physics.utoledo.edu/˜dengx/papers/deng03a.pdf in 2002 by Deng and Schiff). The other major surface of the electrode is a robust transparent conducting and transparent metal oxide (TCO) layer that is anti-reflective, and electrically conductive metal oxide material. Preferably, the TCO layer forms the electrode surface where evolution of gaseous electrolysis product, typically oxygen, occurs.

In a preferred aspect, the metal oxide material (TCO) comprises indium tin oxide, In₂O₃:SnO₂, referred to as ITO.

In another related aspect, the invention provides a photoelectrode comprising a semiconductor layer having one major surface in contact with an electrically conductive substrate and another major surface in contact with the transparent, electrically conductive indium tin oxide (ITO) layer; wherein the semiconductor comprises a photovoltaic, a-Si triple junction material.

More specifically, a corrosion-resistant, transparent conductive coating (TCO) is applied to the surface of a photoelectrochemical device (PEC) to protect the surface from corrosion in basic electrolytes. The TCO, which consisted of a mixture of indium oxide and tin oxide (ITO), is applied on top of the triple junction amorphous silicon solar cell (semiconductor portion of the PEC device) preferably by vacuum sputtering. This produces a durable coating with superior corrosion resistance. The coating is thicker, has larger grain size and better crystal orientation to resist corrosion than conventional ITO films that are applied to many photovoltaic cells as an anti-reflection coating. Exemplary sputtering conditions for the new ITO coating, referred to as ITO-9, are these: sputtering target=90% In₂O₃/10% SnO₂; deposition time=60 min.; substrate temperature=200° C. or more; pressure=8 mTorr; atmosphere=argon containing 0% oxygen; radio frequency (rf) power=40 watts. The thickness of ITO-9 was 4200 Angstroms. The sputtering time was varied to determine the optimum thickness as well as to optimize the other conditions. A range of sputtering conditions was found that produced several more useful coatings that may be superior to the conventional ITO coatings. This range of conditions tested was: temperature=125-260° C., oxygen=0-3% in argon; rf power=40-50 watts.

Before further describing the invention it is useful to understand the limitations of conventional designs. The production of hydrogen and oxygen via photoelectrolysis occurs in a cell wherein the electrolyte may be acidic, alkaline, or neutral. The arrangement of the cell and design of the electrode will be determined, at least in part, by the nature of the electrolyte. Typically, the generation of hydrogen using a photoelectrochemical cell requires a photoelectrode, and at least one counter electrode to the photoelectrode. Both the photoelectrode and its counter electrode are disposed in a suitable container having an electrolyte, which provides the source of hydrogen, and suitable ionic species for facilitating the electrolysis. The electrochemical cell typically utilizes a metal electrode such as Pt or Ni as the counter electrode.

In one arrangement, when the electrolyte is alkaline and the counter electrode is a metallic cathode, the reaction at the counter electrode is: 2H₂O+2e⁻→H₂+2OH⁻.

The reaction in the alkaline electrolyte at the photoelectrode which is a photoanode is: 4OH⁻→O₂+2H₂O+4e⁻.

When the electrolyte is acidic the reactions at the photoanode and at the counter electrode differ from the alkaline case. For example the cathodic reaction is: 2H⁺+2e⁻→H₂. The anodic reaction is: 2H₂O→O₂+4H⁺+4e³¹. Notice that the H₂ is produced at the cathode (the electrode where reduction occurs) and O₂ at the anode (the electrode where oxidation occurs) in either acidic or basic conditions.

In a preferred system with a basic (alkaline) electrolyte, when the semiconductor photoanode is exposed to light, electrons are excited thereby creating holes in the valence band and free electrons in a conduction band. The electrons produced at the photoanode are conducted through an external conductive path to the counter electrode where the electrons combine with the water molecules in the electrolyte to produce hydrogen gas and hydroxide ions. At the photoanode, the electrons are provided from hydroxyl ions in the solution to fill holes created by the departure of excited electrons from the photoanode, and oxygen is evolved. For optimum performance, the semiconductor utilized in the system has a voltage in the necessary range to split water (1.6 to 2.2 volts) and in the preferred embodiment herein, such a semiconductor comprises a triple-junction photovoltaic type cell formed of amorphous silicon material.

Accordingly, the incident sunlight or simulated sunlight (electromagnetic radiation) absorbed in the semiconductor creates electron/hole pairs. The photo-excited electrons are accelerated toward the n-layer of the semiconductor due to the internal electric field at the p-n junction. The holes at the p-n junction are accelerated toward the p-layer of the semiconductor. When electrons and holes are accelerated with sufficient energy (voltage), they can react at the cathode and anode respectively, with ions present in the aqueous solution. Oxygen is evolved at the photoanode and hydrogen is evolved at the counter electrode (cathode) according to the reactions previously described hereinabove with respect to the alkaline or acidic solutions.

Conventional photovoltaic cells for the conversion of light into electricity are coated with TCO coatings. Such coating on the face of such cells is typically used as an anti-reflective coating and to collect the electric current from all parts of the cell surface, so that individual solar cells can be interconnected to form solar modules and panels. Due to their corrosion, such coatings have not heretofore been found suitable for use in the aggressive environment of an electrolysis cell.

Accordingly, one of the problems faced in optimizing conventional devices is the corrosion of the TCO and subsequent destruction of the semiconductor by the electrolyte. Indium-tin oxide coatings have not yet been developed to withstand the environment at such an interface. We found that when an n-type layer is adjacent to the electrolyte (a so-called pin device), and it is attempted to make hydrogen on the irradiated electrode (cathode), in a reducing type process, degradation of the TCO coating immediately occurs in the electrolyte.

Accordingly, the design of the present invention is based upon having the p-type layer adjacent to the robust ITO coating of the invention. This so-called n-1-p device provides a photoanode that can withstand the corrosive anodic production of oxygen. External connection of the anode to a metal counter electrode where hydrogen evolves completes the photoelectrolysis cell. In this preferred cell arrangement, the hydrogen and oxygen production reactions can be physically separated so the gases do not mix.

Because the very aggressive or corrosive reaction of oxygen production is occurring at the n-1-p type electrode (anode) of the present invention, there is a strong tendency for degradation of the coating on the electrode at the electrolyte interface. The present ITO coating of the invention addresses this difficulty by a novel design and method of making such coating and electrodes. By the present invention it is possible to use such coated cells in an electrolysis environment because the design of the present invention provides the more robust ITO-coated electrode surfaces.

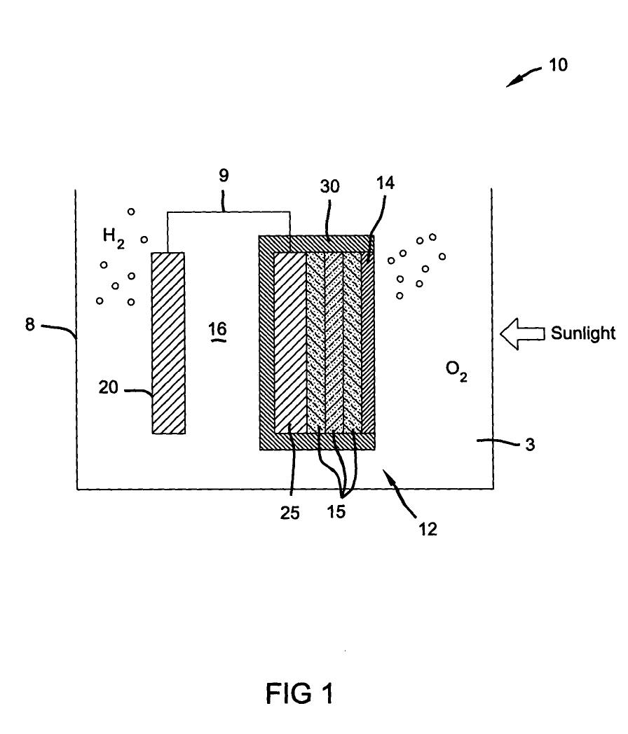

Referring to FIG. 1, there is shown a photoelectrochemical (PEC) device 10 housed in a container 8. The PEC device 10 comprises a PEC photoelectrode 12 and counter electrode 20 connected by conductive wire 9. Layer 14 is an indium tin oxide (ITO), transparent conductive oxide (TCO), surface coating 14 to protect the underlying amorphous silicon (a-silicon) layers 15 of the device from corrosion when immersed in basic electrolytes 16. The side of the electrode 12 facing away from layer 14 is covered by a metal substrate 25. Non-conductive material 30 is arranged around the layers 14, 15 and 25 but does not cover the face of layer 14. The TCO 14, which consisted of indium-tin oxide (ITO), was applied by vacuum sputtering to the outer surface 18 of the triple-junction amorphous silicon solar cell 15. That is, the ITO was applied to the semiconductor portion of the PEC device 10 by vacuum sputtering as described hereinbelow. Vacuum sputtering is described in Deng et al., 1998, “Study of sputter deposition of ITO films for a-Si:H n-i-p solar cells,” in Proceedings of 2^{nd} World Conference and Exhibition on Photovoltaic Solar Energy Conversion, 700-703.

Note that the ITO was applied to the photovoltaic cell as an anti-reflection coating 14 and is also used to conduct electric current from the outer (p-layer) of the triple-junction a-Si solar cell 15. Thus, when the PEC device 10 was exposed to simulated solar radiation, the layer 14 very effectively conducted electric current from the solar cell photoelectrode 12 to the electrolyte (for example, aqueous KOH) 16 to split water and evolve hydrogen at the counter electrode 20 and oxygen at the photoelectrode 12.

The formation of a PEC photoelectrode 12 of FIG. 1 with indium tin oxide coating 14 applied directly on top of the a-Si semiconductor material 15 will now be described with reference to specific materials and method of applying the ITO coating.

In the preferred embodiment of the present invention, the PEC cell comprises a photovoltaic amorphous silicon triple junction cell. Such an amorphous silicon-based cell comprises amorphous silicon thin-film materials deposited by a preferred rf plasma enhanced chemical vapor deposition method (PECVD), as described in Deng and Schiff, 2003, “Amorphous Silicon Based Solar Cells,” Chapter 12, pages 505-565 in Handbook of Photovoltaic Engineering, ed. A. Luque & S. Hegedus, by John Wiley & Sons, Ltd., such chapter separately published on Xunming Deng's website: http://www.physics.utoledo.edu/˜dengx/papers/deng03a.pdf in 2002 by Deng and Schiff. Amorphous silicon and silicon germanium materials for high efficiency triple-junction solar cells are fabricated by United Solar, ECD, Fuji, University of Neuchatel, BP Solar, Canon, University of Toledo and Sharp. For the experiments described herein, the triple-junction amorphous silicon solar cells were purchased from the University of Toledo (Professor Xunming Deng). The process is conducted in an ultra-high vacuum multi-chamber arrangement, in a system isolated from the environment. Preferably two deposition chambers are used. One chamber is used for the growth of a-Si and a-SiGe materials. By alloying the Si with Ge the band gap of the resulting semiconductor, and thus the production of photoelectrons by light quanta, can be adjusted, so that the solar spectrum is more efficiently used. The other is used for the preparation of n-type, a-Si and p-type microcrystalline silicon (pc-Si) layer. In the method, Si₂H₆ GeH₄ and hydrogen are used for the deposition of a-Si and a-SiGe materials, respectively. Deposition of p-layers is accomplished using BF₃ doping, while deposition of n-layers is accomplished using PH₃ doping. The combination of the n- and p-layers, along with an i-layer in between them to improve performance, ultimately forms the a-Si and a-SiGe n-1-p junctions. Even though the triple-junction cells contain Ge, and the amorphous silicon is hydrogenated amorphous silicon (a-Si:H), they are referred to as a-Si cells.

A preferred substrate is stainless steel foil, with or without a silver-zinc oxide back reflector coating, for supporting the silicon-based layers.

The top of the silicon based electrode is covered with the layer of ITO of the invention by use of an rf sputtering chamber, using various mixtures of In₂O₃ and SnO₂ having predominately In₂O₃ and varying amounts of SnO₂, for example 5%, 10% and 15% SnO₂. The preferred sputtering conditions for the ITO coating are these: sputtering target=90% In₂O₃/10% SnO₂; deposition time=60 min; substrate temperature=230° C. or greater; pressure=8 mTorr; atmosphere=argon containing 0% oxygen; radio frequency (rf) power=40 Watts. The thickness of the ITO coating was approximately 4200 Angstroms. The ITO coatings were prepared by a sputtering process as described earlier hereinabove (Proceedings of 2^{nd} World Conference and Exhibition on Photovoltaic Solar Energy Conversion, 1998) and conducted at the University of Toledo.

### EXAMPLE

The samples were prepared using a process called “sputtering”. In this process a target of 90% indium oxide, In₂O₃ and 10% tin oxide SnO₂ was bombarded by argon ions, Ar⁺, from a sputter gun in a vacuum chamber. The Ar⁺ ions dislodge (sputter) material from the target and in a high vacuum chamber the material (ITO) was focused with a magnetron and condensed onto the receiving substrate which was a 2″×2″ stainless steel plate covered by a shadow mask as described below. A total of 20 samples of ITO on stainless steel were prepared and the six listed in Table I were tested using suitable electrochemistry apparatus, to determine the surface coating (ITO) corrosion rates.

Sputtering conditions for six samples tested are shown in Table 1 below which explores some of the sputtering conditions. Basic sputter apparatus and basic operation of same is as described in X. Deng, G. Miller, R. Wang, L. Xu and A. D. Compaan, “Study of sputter deposition of ITO films for a-Si:H n-1-p solar cells”, in Proc. Of Second World Conference and Exhibition on Photovoltaic Solar Energy Conversion and 27th IEEE Photovoltaic Specialist Conference, 700 (1998). This is publication deng98c.pdf listed on the web site: http://www.physics.utoledo.edu/˜dengx/papers/papers.htm.

The following information about the sputtering conditions is pertinent. Stainless steel (ss) substrate, 127 um thick, was used for all ITO coatings. The sputter target in all cases was: ITO (90% In₂O₃/10% SnO₂). Time is the time that the sample was in the “sputtering” chamber. All samples used a thin (0.003″ thick) full-hard 302 stainless steel, 2″×2″ shadow mask (Microphoto Inc., Roseville, Mich.) with 25 square (0.25″×0.25″) openings to cover the substrate. Standard ITO deposition conditions used the 90%/10% by weight In₂O₃:SnO₂ target, rf sputtering, power of 40W, chamber pressure of 8 mTorr of Argon, and 316 L stainless steel (ss) substrate

TABLE 1
Sputtering chamber conditions for the six coatings
chosen for corrosion testing.

| | | | Deposition | | | Oxygen | rf | |
|---|---|---|---|---|---|---|---|---|
| ITO | Sub- | | Time | Temp. | Pressure | % | power | |
| # | strate | Target | (min) | (C.) | (mTorr) | in Ar | (Watts) | Note |
| 1 | ss | 1 | 10 | 195 | 8 | 0 | 40 | Standard condition |
| 3 | ss | 1 | 60 | 210 | 8 | 0 | 40 | 6× thickness |
| 6 | ss | 1 | 60 | 125 | 8 | 0 | 40 | Low T, 6× thickness |
| 8 | ss | 1 | 30 | 260 | 8 | 0.3 | 40 | High T, 3× thickness, O₂ |
| 9 | ss | 1 | 60 | 260 | 8 | 0 | 40 | High T, 6× thickness |
| 17 | ss | 1 | 60 | 260 | 8 | 3 | 40 | High T, very high O₂ |

1. Sputter Target 1: ITO (90% In₂O₃/10% SnO₂) by wt.

Temperature in the above table was estimated by calibrating substrate temperature versus heating power in watts and not the rf power-that is a different variable. This temperature was not routinely measured, but a calibration curve of heating power versus substrate temperature was used. The heating caused by the rf energy was estimated in reference to determining how good the substrate temperature measurements were. The variance was estimated at ±20° C. Another problem in assigning a temperature to the ITO sputtering conditions is that the temperature increases with deposition time. In summary, a standard ITO can be prepared anywhere from 195-215° C., with the preferred being approximately 200° C.

Other sputtering chamber conditions include to prepare the standard ITO include: Ambient: Ar pressure=8 mTorr, deposition time=10 minutes, film thickness=approximately 650-700 Angstroms, and Oxygen partial pressure=0.

Combined voltammetry and Electrochemical Impedance Spectroscopy (EIS) were used to determine the corrosion rate of the six coatings in Table 1. The apparatus consisted of a Perkin Elmer Model 263A Potentiostat/Galvanostat controlled by Electrochemistry Powersuite software. This was used for voltammetry. In addition for Electrochemical Impedance Spectroscopy a Model 5210EC Two Phase Lock-In Amplifier, Powersine software and ZsimpWin Equivalent Circuit Modeling software were used. Each of the ITO coated stainless steel substrates in Table 1 was made into an electrode using the same process earlier described to make ITO-coated amorphous silicon solar cells into PEC cells. This involves attaching the stainless steel bottom side of the ITO coated plate to a wire using a silver-containing conducting epoxy, surrounding the wire with a glass tube and coating all of the exposed parts of the wire and stainless steel substrate with a non-conducting and durable epoxy so that only the ITO is exposed.

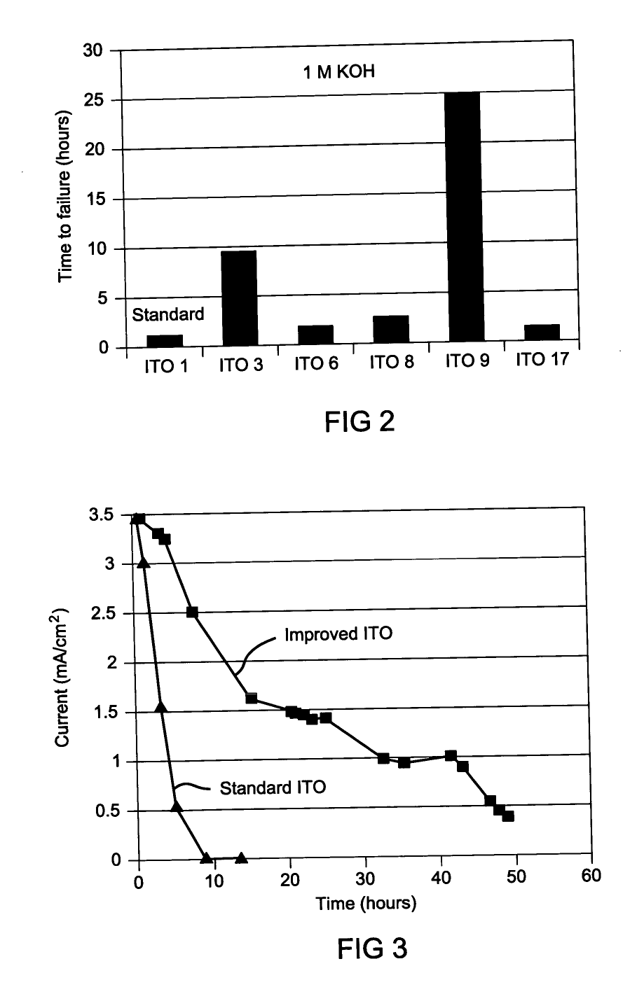

Each of the six electrodes was tested by electrolyzing 1M KOH electrolyte at a potential of 2.2 volts direct current (VDC) and timing the failure due to corrosion indicated by an increase in the current density of the electrode. The ITO-coated electrode, the anode, where oxygen was produced was coupled with a platinum (Pt) electrode as the cathode, where hydrogen was evolved. The potentiostat was operated with a “linear sweep” from 2.1995 to 2.2005 VDC. This is essentially a constant voltage of 2 volts and facilitated use of the potentiostat software to control the experiment and measure the current with a “zero-resistance ammeter”. The sweep time was at least 28 hours. Failure of the electrode due to corrosion was assumed when the current density at the coated surface increased to that of uncoated stainless steel, 12 mA/cm². Pitting corrosion was usually observed on the electrode surface and a dark stain, presumably from MnO₄⁻² could be observed in the solution accompanying the corrosion. The results from the corrosion testing are shown in FIG. 2 below.

EIS was also used to predict the corrosion rate of the ITO-coated electrodes. The EIS technique allowed measurement of the corrosion current caused by immersing each electrode in 0.5 M KOH solution. The results of these measurements also ranked the coating in the same order as the “linear sweep” electrode method discussed above, i.e., ITO-1 had the fastest corrosion rate and ITO-9 had the slowest corrosion rate. Failure was assumed when the corrosion current rose to a high value, similar to uncoated stainless steel immersed in KOH.

In FIG. 2 it is seen that all of the coatings tested had superior corrosion resistance compared to the standard coating (ITO-1). In particular, based on the corrosion data, ITO-9 had a lifetime approximately 17 times as long as ITO-1.

Table 2 below shows an abbreviated listing of the analytical techniques used to characterize the six coatings of interest based on the corrosion testing described above. The techniques included: 1) X-ray diffraction (XRD) analysis to examine the degree of crystallinity of the coatings; 2) Electron probe microanalysis (EPMA) to determine the coating composition and coating weights; 3) scanning electron microscopy (SEM) to determine the grain size and structure; 4) X-ray fluorescence (XRF) to determine the approximate coating weights; and 5) X-ray photoelectron spectroscopy XPS) with depth profiling to determine the coating composition and thickness. Some of the earlier analyses were to determine the uniformity of the ITO films as prepared, the coating weights before and after corrosion testing and the chemical composition of the films.

A systematic study of samples of ITO-1, ITO-3, ITO-6, ITO-8, ITO-9 and ITO-17 was performed to determine the cause of the unexpectedly good performance of ITO-9. This is the most important information since it relates the corrosion results directly to the film properties. The results are in the second column of Table 2. Without wishing to be held to any particular theory, there are several explanations as to why some ITO coatings perform better in the corrosion tests than others. The possibilities include: 1) coating composition, 2) thickness, 3) porosity, 4) density, 5) grain size, 6) crystallinity, and 7) crystal orientation (texture). By examining the characterization results from SEM, EPMA, and XRD, in Table 2 along with the relative corrosion performance of the coatings, each of the explanations can be considered and some can be discounted as explanations. First, regarding composition, EPMA shows only small (10%) changes in the Sn:In ratio among the coatings, and the results do not correlate with the corrosion performance. Second, looking at coating thickness, there were 3 thick coatings, 2 thin coatings, and 1 intermediate-thickness coating. While the thick coatings generally did better than the thin coatings, one of the 3 thick coatings was a poor performer, as was the intermediate-thickness coating. Third for porosity, only the 2 thinnest coatings showed indications of porosity in the SEM photos, while the others appeared to have full coverage. So while it is important that the coatings be non-porous, some other property is required to give good corrosion performance. Fourth, the x-ray powder diffraction line results showed that all the coatings have a 1% lattice expansion compared to a reference coating, so the coating density is nearly the same. The small differences in lattice parameters that were observed did not correlate with the corrosion performance. Fifth, for the 4 coatings that had definable grain sizes as determined using SEM (Table 2), that parameter did not correlate with the corrosion performance. Sixth, the worst-performing coating in FIG. 2 was the least crystalline, so crystallinity may be a consideration in corrosion performance. The two best-performing coatings gave the most distinctive diffraction patterns. Those two coatings also included a small amount of hexagonal-phase oxide together with the predominant cubic-phase oxide. Seventh, regarding crystal orientation, the two best performing coatings, and especially ITO-9, the best-performing coating, had a 222 fiber texture based on the XRD results (Table 2). A 222 fiber structure means the crystals are on the steel substrate with the 222 planes parallel to the surface, but that each columnar grain is randomly rotated about its z axis. Thus, the ITO-9 coating of the invention is characterized as a highly oriented film, having highly oriented crystals, and which is highly crystalline. This is evident from the above data with comparison to a standard ITO coating, such as ITO-1. Thus, it is concluded that crystallinity and crystal orientation are important in optimizing ITO coatings for corrosion performance. The best performing coatings were sputter-deposited at higher substrate temperatures, for longer times, and with no oxygen added to the sputter gas. This last observation is significant because it is in disagreement with work reported elsewhere. See E. Miller and R. Rocheleau, “Photoelectrochemical hydrogen production,” in Proc. of the 2000 Hydrogen Program Review, NREL-570-28890, U.S. Dept. of Energy National Renewable Energy Laboratory, 2000., and W.-F. Wu and B.-S. Chiou, “Effect of oxygen concentration in the sputtering ambient on the microstructure, electrical and optical properties of radio-frequency magnetron-sputtered indium tin oxide films,” Semicond. Sci. Technol., 11, 196-202 (1996). Miller and Rocheleau found that the presence of 0.25% O₂, in addition to a high temperature, gave a better-performing film. Wu and Cjiou needed almost 3% O₂ to prevent blackened films from substoichiometric oxides. In the present invention, there were no blackened films under any deposition conditions. Further, not only did the addition of O₂ not help the film corrosion performance or crystal texture, but oxygen also significantly lowered the sputter-deposition efficiency. These results show that the addition of oxygen to the argon sputter gas gives much lower efficiencies, as well as poorer corrosion performance.

Table 2. Summary of chemical analyses of samples relevant to determining the composition and morphology of the six ITO coatings in Table 1.

TABLE 1

| Analytical | |
|---|---|
| Technique | Finding |
| SEM | ITO-1 and ITO-8 had thin, ill-defined grain sizes. |
| | The grain sizes for ITO-3, ITO-6, ITO-9 and ITO- |
| | 17 were 66, 53, 59, and 44 nm, respectively. Only |
| | the thinnest films (ITO-1 and ITO-8) showed any |
| | porosity; all of the others appeared to have full |
| | coverage. |
| EPMA | The Sn:ln atom ratio varied from 0.115 to 0.123 |
| | for the six coatings. This is considered a small |
| | variation in the composition. Also, EPMA showed |
| | that the presence of O₂ in the sputter gas lowered |
| | the ITO deposition efficiency, i.e., gave a thinner |
| | coating. |
| XPS | Sputter profiles for a thin (ITO-1) and a thick (ITO- |
| | 3) coating reveled that the coatings had a uniform |
| | composition with respect to depth. |
| Powder | The crystalline fraction of the ITO film consists |
| XRD | predominantly of cubic indium oxide crystal |
| | structure. A small amount of hexagonal indium |
| | oxide crystal structure was detected in ITO-3 and |
| | ITO-9. Based on an assessment of the crystal |
| | quality and crystallographic texture using a |
| | diffractometer, it was concluded that even though |
| | ITO-1 and ITO-8 have comparable thicknesses, |
| | the coating on ITO-1 is poorly crystallized. |
| XRF | Examination of the corners and middle of |
| | individual 0.25″ × 0.25″ ITO squares reveled that |
| | the individual squares had uniform ITO coating |
| | weights. Also, examination of the four corner |
| | squares and middle square of a 2″ × 2″ ITO |
| | specimen (five of the 25 squares), reveled that the |
| | coating weights were uniform across the different |
| | squares. |

Next, PEC cells were made using a variety of ITO sputtering conditions, substrate temperature and ITO thickness, and with and without O₂ present. The conditions included conditions approximating those of ITO-1, the standard ITO used as an antireflection coating in solar cells; and ITO-9, the most corrosion resistant coating discovered in our corrosion testing. These photoelectrodes were tested to measure their water splitting ability and lifetime in PEC cells. Interestingly the water splitting properties for PEC devices employing ITO coatings applied to triple junction a-Si cells at the highest temperatures and thickest coating conditions that we explored in the corrosion testing were not better than other comparative coatings. See Table 1, conditions of 260° C. and 60 minutes. That is, the conditions that produced the most corrosion-resistant electrodes on stainless steel substrates produced photoelectrodes with relatively lower voltage outputs. Apparently, the higher temperature and longer time to make the thicker coatings negatively impacted the a-Si cells. It may be possible to provide sufficiently thick ITO coatings at the higher temperatures by reducing the time it takes to deposit the ITO coating, leading to superior durability and water splitting performance.

Here it has been demonstrated superior ITO coatings on a-Si cells at temperatures as high as 230° C. together with deposition times that produced the thicker coatings. Even these conditions, which for temperature was somewhere between those for ITO-3 and ITO-9, there was a marked increase in the PEC water-splitting lifetime using our Omega 24-watt metal-halide solar simulator with an output between 120 and 140 mW/cm². As shown in FIG. 3 below, PEC cells prepared with the improved ITO coating lasted significantly longer, 42 hours, than the cells prepared at lower temperatures and with shorter deposition times having thinner coatings.

TABLE 3
Conditions used to prepare the two PEC cells in FIG. 3.

| | | Deposition | | | Oxygen | rf | |
|---|---|---|---|---|---|---|---|
| Cell | | Time | Temp. | Pressure | % | power | |
| No. | Target | (min) | (° C.) | (mTorr) | in Ar | (Watts) | Note |
| GD951-1 | 1 | 8.25 | 210 | 8 | 0 | 50 | Approx. std. condition |
| GD966-1 | 1 | 60 | 230 | 8 | 0 | 50 | Higher T, thicker |

1. Sputter Target 1: ITO (90% In₂O₃/10% SnO₂).

In summary, we found that more durable (corrosion resistant) ITO coatings are produced at higher temperatures, longer deposition times, and with no oxygen present in the sputtering apparatus. In particular, our results are in contrast to those discussed earlier showing films deposited at temperatures less than preferred here and with O₂ present in the sputtering gas.

Accordingly, it was determined that water could be split into hydrogen and oxygen by electrolysis in a basic electrolyte (aqueous KOH solution) for over 42 hours before the PEC cell gradually failed due to corrosion of the ITO-coated electrode. This lifetime of more than 42 hours was significantly greater than the lifetime of approximately 1 hour shown by electrodes coated with a standard conventional ITO coating deposited at 210° C. with 0% oxygen and a sputtering time of 8.25 minutes. Electrolysis (water splitting) required a potential of 1.6 to 2.2 volts and produced a current density on the ITO coated electrode of 3-3.5 mA/cm². This current was supplied by a thin film triple junction amorphous silicon solar cell within the PEC device using solar energy simulated using a calibrated metal-halide light source. These improved photoelectrodes were coated with improved (more-corrosion resistant) ITO layers by the vacuum sputtering methods of the invention.

The superior corrosion resistance of ITO coatings prepared at higher temperatures, for longer deposition times (thicker), and with no O₂ present in the sputtering chamber when used in PEC cells to split water was consistent with their performance monitored by the corrosion testing discussed earlier.

Finally, it should be noted that the aforesaid solar cells have three pin junctions to utilize a wide range of the solar spectrum using a technique called “spectrum splitting”. The upper cell (pin junction) utilizes the ultraviolet and some of the visible region of the solar spectrum to generate photoelectrons. The middle cell uses the visible and some portion of the infrared region, while the bottom cell uses some of the visible more of the infrared region to generate photoelectrons. The three cells are arranged in series so their respective voltages are added together. The bottom layer, meaning that layer adjacent the zinc oxide/silver/stainless steel substrate in the preferred semiconductor of the present invention, is the n-type semiconductor of the bottom cell. The top layer, meaning the layer adjacent to the ITO, is the p-layer of the top cell. There are intermediate i-layers between the n- and p-layers of each cell.

The series electrical arrangement of the aforesaid three cells makes it possible to achieve a potential of over 2 volts suitable for the electrolysis of water. Theoretically, it is possible to electrolyze water at 1.23 volts. With inherent losses, referred to as over voltages, a potential of at least 1.6 volts is needed for water electrolysis. Thus, the approximately 2-volt potential produced by the triple-junction a-Si arrangement is quite satisfactory.

Several types of multijunction solar cells are known for direct conversion of sunlight to electricity in a-Si photovoltaics. Dual-junction a-Si/a-SiGe cells and triple junction a Si/a-SiGe/a-SiGe cells enable a “spectrum splitting” to collect the sunlight, and this achieves higher conversion efficiencies. It is known that a-Si(1.8 eV)/a-SiGe(1.6 eV)/a-SiGe (1.4 eV) triple-junction solar cells are among the most efficient a-Si based cells.

Discussion of the design, construction, and advantages of amorphous silicon solar cells, including triple-junction amorphous silicon solar cells is contained in Deng and Schiff, 2003, “Amorphous Silicon Based Solar Cells,” Chapter 12, pages 505-565 in Handbook of Photovoltaic Engineering, ed. A. Luque & S. Hegedus, by John Wiley & Sons, Ltd., such chapter separately published on Xunming Deng's website: http://www.physics.utoledo.edu/˜dengx/papers/deng03a.pdf in 2002 by Deng and Schiff. A review of the basic photoelectrochemical properties of amorphous silicon based structures can be found in Proceedings of the 2002 U.S. DOE Hydrogen Program Review NREUCP-610-32405 entitled, “Photoelectrochemical Systems for Hydrogen Production”, authored by Varner et al., 2002; and “Proceedings of the 2000 Hydrogen Program Review” NREL-570-28890 entitled, “Photoelectrochemical Hydrogen Production”, authored by Miller and Rocheleau, 2000.

The invention described here comprises a photoelectrochemical (PEC) device made from an inexpensive triple-junction amorphous silicon (a-Si) solar cell that is protected from corrosion by a durable, transparent, and electrically conductive material. This design results in a practical method for direct generation of hydrogen by in-situ electrolysis of water. Such a system can potentially produce large quantities of hydrogen much more cheaply by eliminating the elaborate electric collection grid and mounting needed by photovoltaic cells. In PEC devices, greater efficiency is achieved by supplying electrons from the active silicon directly through the shortest distance to catalyst layers deposited on the outside where hydrogen and oxygen are evolved. Each of the three stacked solar cells in the triple-junction device absorbs a portion of the solar spectrum and is used to boost the voltage output of the device to over two volts—more than enough to split water (it takes a minimum of 1.23 volts to split water, and for practical purposes more than 1.6 volts is needed to overcome “overvoltage” effects at the electrodes). Here, a-Si cells are inexpensive compared to crystalline or polycrystalline-silicon and especially compared to highly efficient but very expensive crystalline semiconductor wafers such as GaAs, GalnP₂, and AlGaAs. In addition, a variety of bases may be used besides KOH, such as Na₂CO₃ or NaOH. Use of acids and neutral salts are within the scope of the invention to produce the aqueous electrolyte.

The description of the invention is merely exemplary in nature and, thus, variations that do not depart from the gist of the invention are intended to be within the scope of the invention. Such variations are not to be regarded as a departure from the spirit and scope of the invention.

1. (cancelled)

2. (cancelled)

3. (cancelled)

4. (cancelled)

5. (cancelled)

6. (cancelled)

7. (cancelled)

8. (cancelled)

9. (cancelled)

10. (cancelled)

11. (cancelled)

12. (cancelled)

13. (cancelled)

14. A photoelectrode comprising a semiconductor layer having first and second opposite major surfaces, said first major surface overlaid with a layer of indium tin oxide (ITO) having a thickness of at least 4000 Angstroms.

15. The photoelectrode of claim 14 wherein said semiconductor layer comprises photovoltaic, amorphous, silicon n-1-p material; and said indium tin oxide layer overlies p of said n-1-p.

16. The photoelectrode of claim 14 wherein said semiconductor layer second major surface is in contact with an electrically conductive substrate.

17. The photoelectrode of claim 16 wherein said photoelectrode comprises in order: said electrically conductive substrate comprising ss/Ag/ZnO, and said semiconductor comprising n-1-p; wherein said n-layer faces said ZnO, and said ITO layer overlies said p-layer.

18. A photoelectrode comprising a semiconductor layer having a surface overlaid with an indium tin oxide (ITO) layer in the form of a highly oriented film.

19. A photoelectrode comprising a semiconductor layer having a surface overlaid with an indium tin oxide (ITO) layer which comprises predominantly a cubic-phase oxide and a smaller amount by weight of a hexagonal-phase oxide.

20. A photoelectrochemical device for electrolysis of water to produce hydrogen comprising:
a container housing a photoelectrode, a counter electrode and an electrolyte solution, said photoelectrode and said counter electrode spaced apart from one another in said container and each being in contact with said electrolyte solution;
said photoelectrode comprising:
a semiconductor layer having a first major surface coated with an indium tin oxide (ITO) layer having a thickness of greater than 3000 Angstroms; and a second major surface in contact with an electrically conductive substrate;
said counter electrode comprising a metal;
said solution comprising a solvent which comprises water and a solute which comprises a base; and
an electrically conductive path external to the solution between said photoelectrode and said counter electrode.

21. The device of claim 20 wherein said indium tin oxide layer is formed by generating a flux of material by bombarding a target comprising indium oxide and tin oxide and collecting said material on said first major surface of said semiconductor layer.

22. The device of claim 20 wherein said photoelectrode comprises in order: said electrically conductive substrate comprising ss/Ag/ZnO, and said semiconductor comprising n-1-p; wherein said n-layer faces said ZnO, and said ITO layer overlies said p-layer.

23. A photoelectrochemical device for electrolysis of water to produce hydrogen comprising:
a container housing a photoelectrode, a counter electrode and an electrolyte solution, said photoelectrode and said counter electrode spaced apart from one another in said container and each being in contact with said electrolyte solution;
said photoelectrode comprising:
a semiconductor layer having a major surface coated with an indium tin oxide (ITO) layer in the form of a highly oriented film.

24. The device of claim 23 wherein said ITO layer comprises predominantly a cubic-phase oxide and a smaller amount by weight of a hexagonal-phase oxide.

25. The device of claim 20 wherein said indium tin oxide (ITO) layer is formed by:
generating a flux of material by bombarding a target comprising indium oxide and tin oxide for a time of at least 30 minutes at a temperature of at least 200° C. in a non-oxidizing atmosphere; and
collecting said material on said surface of said semiconductor layer to form said ITO layer thereon.

26. The device of claim 25 wherein said generating a flux of material by bombarding a target is conducted by sputter deposition.

27. The device of claim 25 wherein said non-oxidizing atmosphere is an inert atmosphere.

28. The device of claim 25 wherein said non-oxidizing atmosphere comprises argon.

29. The device of claim 25 wherein said non-oxidizing atmosphere is essentially oxygen-free.

30. The device of claim 25 wherein said temperature is at least 230° C.

31. The device of claim 25 wherein said time is at least 60 minutes.

32. The device of claim 25 wherein on the basis of 100 parts by weight, the indium oxide constitutes 90 parts and the tin oxide constitutes the balance.

33. The device of claim 25 wherein the ITO layer comprises predominately a cubic-phase oxide and a smaller amount by weight of a hexagonal-phase oxide.

34. The device of claim 25 wherein the ITO layer comprises a highly oriented film of highly oriented crystals.

35. The device of claim 25 wherein the indium oxide is represented by In₂O₃ and the tin oxide is represented by SnO₂.

36. The device of claim 20 wherein said ITO layer is formed by bombarding a target, where on the basis of 100 parts by weight of the target, indium oxide constitutes 90 parts, in a non-oxidizing atmosphere for a time and at a temperature sufficient to deposit said layer of ITO.

37. The device of claim 36 wherein said thickness is greater than 4000 Angstroms and the target consists essentially of 90 parts indium oxide and ten parts tin oxide by weight.
